(19) United States
(12) Patent Application Publication
(10) Pub. No.: US 2003/0108802 A1
(43) Pub. Date: Jun. 12, 2003

(54) Planar and fiber optical grating structures fabrication apparatus and method

(76) Inventor: Arkady Bablumyan, La Jolla, CA (US)

Correspondence Address: Eastman & Associates, Suite 1800, 707 Broadway Street, San Diego, CA, 92101, US

(21) Appl. No.: 10/209,251

(22) Filed: Jul. 30, 2002

Related U.S. Application Data
(60) Provisional application No. 60/326,047, filed on Sep. 26, 2001.

(51) Int. Cl. G03F 9/00; G03H 1/02

(52) U.S. Cl. 430/1; 430/5; 359/3

(57) ABSTRACT

A planar and fiber optical grating structure includes a phase mask that intrinsically contains apodization. The phase mask is a volume hologram resulting from refractive index change in the media. The apodized volume hologram phase mask incorporates a change in diffraction efficiency along its length without a reduction in the average transmittance through the mask, and without changing the average refractive index of the grating along the full length of the grating. The phase mask intrinsically produces exactly two diffraction orders, the zero order and the first order, and is functional over a wavelength range greater than 10 nanometers without substantive interference from undesired diffraction orders while still maintaining adequate channel isolation.

### 1. RELATED APPLICATIONS

This application claims the benefit of priority to co-pending provisional patent application, Ser. No. 60/326,047, filed on Sep. 26, 2001 and entitled “Fiber Bragg Grating.”

### BACKGROUND

2. The Field of the Invention

This invention relates to light guiding structures and methods of forming and producing the same and, more particularly, to novel systems and methods for producing optical waveguide, optical masks, integrated optical devices, optical grating structures and photonic devices using the same.

3. Background

Optical fibers and optical waveguides as currently used in the industry consist of an optically transparent core material having a 1st refractive index and a cladding material around the core material having a 2nd refractive index that is lower than the 1st. Differences in refractive index in the fiber cross-section are intentionally designed to confine the optical signal within the fiber core. Conversely, differences in refractive index that occur in the longitudinal dimension of the core or cladding of an optical fiber result in an optical signal mismatch, and consequently a reflection for at least some wavelengths. Unintentional mismatches, when present, cause undesired reflections. In a fiber Bragg grating periodic mismatches in refractive index are intentional. Even so, it is desirable to keep the average refractive index of the grating at an essentially constant level and minimize perturbing signals traversing the fiber. Failure to match the average refractive index of the Bragg grating to the intrinsic refractive index of the optical fiber results in reflection, diminished signal transmission amplitude, and degraded performance. One of the challenges of making a satisfactory fiber Bragg grating is to match the average refractive index of the core to the core refractive index of the unperturbed connecting fiber.

The process of inscribing a Bragg grating into an optical fiber involves using actinic radiation. Actinic radiation is radiation that induces a chemical change of some sort in susceptible media. The actinic change of most current interest is a change in the refractive index of optically transmissive material. Commonly, an ultraviolet source is used as the actinic radiation source to induce photo-refractive changes in optical media such as optical fiber, planar optical waveguide media, silica-based materials doped with hydrogen, germanium, boron, and numerous other such dopants and combinations thereof. Nuclear sources have also been successfully used to produce actinic radiation for optical media inscription. Less energetic wavelengths in the infrared wavelength range can also produce some actinic effects. Optical Bragg gratings are formed by exposing actinicly susceptible material to a suitable periodic or quasi-periodic radiation pattern.

Two approaches to produce the requisite radiation pattern are 1. Interometric exposure, and 2. Masking. The interferometric approach, often referred to as the “holographic” method, involves generating two mutually coherent beams from a common radiation source and combining them to produce an interference pattern having feature dimensions on the order of the wavelength of the radiation used for the exposure. Stability on the order of the optical wavelengths being used is required. Because of the stringent stability requirements for the interferometric approach, it is best suited for research environments where stability can be adequately maintained.

The masking approach involves passing radiation from an actinic source through a mask that modifies the radiation amplitude and/or phase content before exposing the actinicly susceptible media. Commonly used phase masks are relief-type masks. When the masking technique is employed, a mask must first be made, which can then be reused for the exposure of optical media repeatedly.

The diffraction pattern produced by electromagnetic radiation passing through a mask typically has a main lobe of intensity in addition to secondary lobes of lesser intensity. The secondary lobes are usually unwanted, and steps may be taken to minimize them. The process of side-lobe reduction and elimination may involve apodization. The apodization process in optics and other areas of electromagnetics involves the removal or minimization of side lobes that result from a diffraction pattern. It is desirable to minimize the energy in the side lobes. The presence of the side lobe energy degrades the resolvability of the main lobe. The apodization process reduces the amplitude of side lobes and simultaneously maintains the spectral width of the main lobe to within a reasonably close proximity to the first null points of the main lobe.

Approaches to obtain apodized gratings in optical media involve: 1. Varying the grating diffraction efficiency by changing the ridge depth of relief-type phase masks, 2. Using multi-step actinic exposure of the optical media (involving multiple amplitude masks and a phase mask), 3. Using a periodic time-modulated or amplitude-modulated actinic source, 4. Using relative motion involving the actinic radiation beam, a phase mask, and the actinicly susceptible media, 5. Spatial filtering in conjunction with a phase mask. Each approach has its set of limitations or constraints.

Changing the ridge-depth of relief-type phase mask increases the magnitude of undesired side lobes. Additional processing steps (multi-step approach) cost time and resources. Time and amplitude modulation require time and relative motion that require mechanical stability on the order of the wavelength of light. Single step spatial filtering of traditional approaches introduces offsets to the average refractive index of the optical fiber or other optical media that decrease transmission and increase reflections in the optical system.

When the phase mask process is used to fabricate a grating, two gratings are made. First the phase mask grating is produced, and then the optical waveguides or fiber gratings are fabricated. The phase mask grating can ordinarily be used multiple times. For production purposes, making the phase mask constitutes a significant initial expense. How efficiently the production process using the phase mask can function to produce waveguide gratings is a second issue of concern. Both the phase mask grating and the optical media grating are high precision devices requiring fabrication processes that can provide optical precision to within fractions of an optical wavelength. From a production perspective it is advantageous to simplify, shorten, and minimize the total number of steps and shift demanding processes out of the repetitive production phase, if possible. Production steps cost time, material, and capital equipment resources.

The most widely used phase masks are of the relief-type. Various difficulties exist in conjunction with, or as a result of using such masks. Deficiencies of the current art include the following:

1. The relief-type phase-mask (RTPM) process requires expensive optically flat fused silica etched substrates. The blanks and the etching are expensive.

2. The resultant mask have a very narrow, essentially “single-wavelength”, usable region that does not exceed 10 nanometers (nm) in width. Attempts to use the mask at wavelengths other than the one for which it was designed result in rapidly increasing magnitude of unwanted side lobes. Channel isolation is lost. The mask ends up being usable to produce essentially one single channel of a wavelength band.

3. The RTPM process produces undesired diffraction orders, yielding a lower quality grating and poorer channel isolation.

4. Simple exposure of RTPM produces an offset in the average refractive index of the optical fiber or planar waveguide structure that degrades parameters of the grating structure.

5. To minimize the undesired offset in refractive index present with standard RTPM processing, multi-step RTPM processes have been designed that increase processing time and cost.

6. RTPM architecture is not easily amenable to apodization—a necessary element if undesired side lobes and adequate channel isolation levels are to be obtained.

7. Current apodization approaches either increase side lobes (unwanted diffraction orders), offset the average core refractive index and produce chirping, mismatch, unwanted reflections, and signal degradation, or rely upon a multi-step exposure process in production which increases the cost of production in time, materials, and production complexity.

What is lacking in the prior art is a means of including apodization into a phase mask without increasing the magnitude of undesired diffraction orders, in order to meet desired channel isolation criteria. Specific elements lacking in the prior art include:

1. A phase mask that intrinsically produces exactly 2 diffraction orders having diffraction order magnitudes suitable for production of Bragg gratings having substantial modulation depth.

2. A phase mask having a usable wavelength range greater than 10 nm (without undesired diffraction orders to destroy the applicable channel isolation).

3. A phase mask having apodization intrinsically incorporated therein without reducing the total mask transmissivity (which affects the average refractive index over the grating region).

4. A phase mask apodization means that does not increase number (and i.e. cost) of grating production steps or processing time

5. A single step, grating apodization means.

6. A phase mask that provides apodization intrinsically without concomitantly increasing either the magnitude of undesired diffraction orders or the grating length required for a fixed level of channel isolation.

7. A phase mask that easily facilitates the elimination of wavefront distortion without increasing other sources of error such as increased side-lobe component magnitudes, or requiring essentially optically flat interface surfaces.

### BRIEF SUMMARY AND OBJECTS OF THE INVENTION

It might appear that attaching an amplitude mask to a relief mask would produce a suitable apodized phase mask, but such is not the case. Amplitude masks make the light flux inhomogeneous along an actinicly susceptible optical media, such as optical fiber and waveguide substrates. Thus using an amplitude mask to apodize a mask results in a different average change in refractive index to the actinicly susceptible media. The result is a mismatch in the average refractive index when passing from an unexposed portion of the optically transmissive media 8 to an exposed region 9 of the optical media 8.

### BENEFITS AND OBJECTS OF THE PRESENT INVENTION

Some embodiments of the present invention incorporate apodization by adjusting the diffraction efficiency of a volume hologram phase mask, while concomitantly producing the desired average refractive index change that would have been obtained from actinic exposure without having used an amplitude-reducing amplitude mask. This distinction has dramatic consequences in simplifying the processing required to produce apodized grating structures, the size of the resultant structure, and quality of the same.

Consistent with the foregoing objects, and in accordance with the invention as embodied and broadly described herein, an apparatus and method are disclosed, in suitable detail to enable one of ordinary skill in the art to make and use the invention. In certain embodiments an apparatus and method in accordance with the present invention may include but are not limited to providing:

1. A phase mask that intrinsically contains apodization without changing the average refractive index of the grating along the full length of the grating.

2. A phase mask that is a volume hologram (resulting from refractive index change in the media) as opposed to a surface relief (indentation) pattern on the surface of fused silica.

3. A volume hologram phase mask that has apodization intrinsically incorporated therein

4. An apodized volume hologram phase mask that incorporates a change in diffraction efficiency along its longitudinal extent without a reduction in the average transmittance through the mask.

5. A phase mask that intrinsically produces exactly two diffraction orders, the zero order and the first order.

6. A phase mask functional over a wavelength range greater than 10 nanometers without substantive interference from undesired diffraction orders (while still maintaining adequate channel isolation).

7. A broadband phase mask functional over a wavelength band of 100 nanometers.

8. A volume hologram phase mask composed of dichromated gelatin (DCG)

9. A phase mask composed of non-optically flat materials, resulting in significant cost reduction for an otherwise expensive device.

10. A phase mask that can meet or exceed that of existing techniques at a fraction of the cost (roughly 100 time less expensive for materials cost)

11. A phase mask that is actinicly formed using the near ultraviolet wavelength range while still capable of producing masks and gratings operable over wavelength ranging from the near ultraviolet, through the visible and into the infrared.

12. The ability to compensate for wavefront distortion of small-radius fibers and non-optically flat material surfaces, which is otherwise difficult, if not impossible, without requiring specially fabricated specialized geometry intermediate structures.

13. The ability to incorporate apodization into a phase mask and compensate for wavefront distortion without increasing other types of distortion, in conjunction with the ability to minimize unwanted diffraction orders using relatively low-cost volumetric media makes the present invention capable of providing more finely resolved Bragg structures at a significantly reduced cost.

14. A process that is significantly cheaper than existing relief-type mask processes

15 A process that produces a higher quality grating in a shorter device geometry.

17. A volume hologram optical device that contains apodization intrinsically incorporated therein

18. An optical device consisting of an apodized volume hologram that incorporates a change in diffraction efficiency throughout its spatial extent to effect apodization, without substantive reduction in average transmittance therethrough.

19. A volume hologram optical grating functional over a wavelength range greater than 10 nanometers while still maintaining adequate isolation between adjacent wavelength regions.

20. A broadband optical grating capable of operation over a wavelength band of 100 nanometers.

21. An optical device that is actinicly formed using the near ultraviolet wavelength range but is operable in one or more of the wavelength ranges from the near ultraviolet through the infrared.

22. The ability to compensate for wavefront distortion occurring at geometrical feature-sizes of small effective radii and for non-optically flat material surfaces, without the use of specially fabricated specialized geometry intermediate structures.

23. The ability to compensate for wavefront distortion without increasing other types of distortion, such as unwanted diffraction components.

24. An optical device composed of non-optically flat materials, while still providing optical precision resulting in significant cost reduction

### BRIEF DESCRIPTION OF THE DRAWINGS

The foregoing and other objects and features of the present invention will become more fully apparent from the following description and appended claims, taken in conjunction with the accompanying drawings. Understanding that these drawings depict only typical embodiments of the invention and are, therefore, not to be considered limiting of its scope, the invention will be described with additional specificity and detail through use of the accompanying drawings in which:

FIG. 1 is a view of actinic inscription apparatus with radiation, mask, and optical. fiber media;

FIG. 2 is a view of actinic inscription apparatus with radiation, mask, planar optical device and optical waveguide;

FIG. 3 is a view of relief-type phase mask, incident radiation, and resultant diffraction orders;

FIG. 4 is a spatial profile of mask diffraction including the principal diffraction lobe and secondary side lobes;

FIG. 5 is a view of relief-type phase mask, incident radiation, and resultant diffraction orders altered by grating ridge depth;

FIG. 6 is a profile for a relief-type phase mask showing its usable range as a function of wavelength and amplitude;

FIG. 7 is a filter profile of exposed optical grating media showing, the main lobe, side lobes, and noise level as a function of wavelength and amplitude;

FIG. 8 is the transmission and reflection filter profiles for an idealized narrow bandwidth optical filter of exposed optical grating media showing, the main lobe and the absence of side lobes, as a function of wavelength and amplitude;

FIG. 9 is a view of relief-type phase mask with apodization formed by varying slot-depths;

FIG. 10 is a view of core index profile and average refractive index offset across the grating region for unapodized average offset, apodized varying average offset, unapodized core index matching, and multi-step apodized core index matching phase masks as a function of position and refractive index;

FIG. 11 is a view of core index profile and average refractive index offset across the grating region for one embodiment of an ideal apodized core index matching phase mask, according to the invention described herein.

FIG. 12 is a view of multi-step apodization using a relief-type phase, mask with amplitude masks;

FIG. 13 is a view of optical fiber media exposure through a relief-type phase mask using actinic radiation;

FIG. 14 is a view of a volume hologram phase mask according to the invention having incident radiation and exactly two diffracted orders;

FIG. 15 is the wavelength range profile of a volume hologram phase mask fabricated according to the invention;

FIG. 16 is a view of the apodization profile of a volume hologram phase mask according to the invention;

FIG. 17 is a view of apparatus used to write apodized volume hologram phase masks;

FIG. 18 is a view of apparatus used to write apodized volume hologram phase masks using an apodized volume hologram phase mask as the exposure mask through which actinic radiation is passed;

FIG. 19 is a view of filter profiles with main lobe and unwanted side lobes as a function of wavelength and transmission amplitude for a generic unapodized filter, and for an apodized filter according to the invention;

FIG. 20 is a view of measured filter profile data showing the main lobe and unwanted side lobes as a function of wavelength and transmission amplitude for a generic unapodized filter;

FIG. 21 is a view of measured filter profile data showing the main lobe relative to the noise background as a function of wavelength and transmission amplitude for an apodized filter according to the invention;

FIG. 22 is a view of a filter profile as a function of wavelength and transmission amplitude for an apodized filter fabricated according to the invention;

FIG. 23 is a view of a more complicated filter profile as a function of wavelength and transmission amplitude for an apodized filter fabricated according to the invention;

FIG. 24A is a view of wavefront distortion caused by the refractive index difference at the interface between a flat phase mask and an optical fiber;

FIG. 24B is a view of apparatus for the elimination of wavefront distortion between a phase mask and waveguide media enabled by the present invention;

FIG. 25 is a view of apparatus for the elimination of wavefront distortion between a volume hologram phase mask and waveguide media during the actinic inscription process;

FIG. 26 shows preparation steps for dichromated gelatin which is one preferred embodiment of volume holographic media used to fabricate optical gratings, filters, intrinsically apqdized phase masks, planar waveguide devices and the like in accordance with the invention;

FIG. 27 shows development process steps for exposed dichromated gelatin used as the volume holographic media in accordance with the invention;

FIG. 28 is a view of the amplitude profile as a function of transmission amplitude and position for the amplitude mask used to incorporate apodization into the volume hologram phase mask according to the invention; and

FIG. 29 is the phase profile as a function of phase shift and position for a volume hologram phase mask according to the invention.

### DETAILED DESCRIPTION OF THE PREFERRED EMBODIMENTS

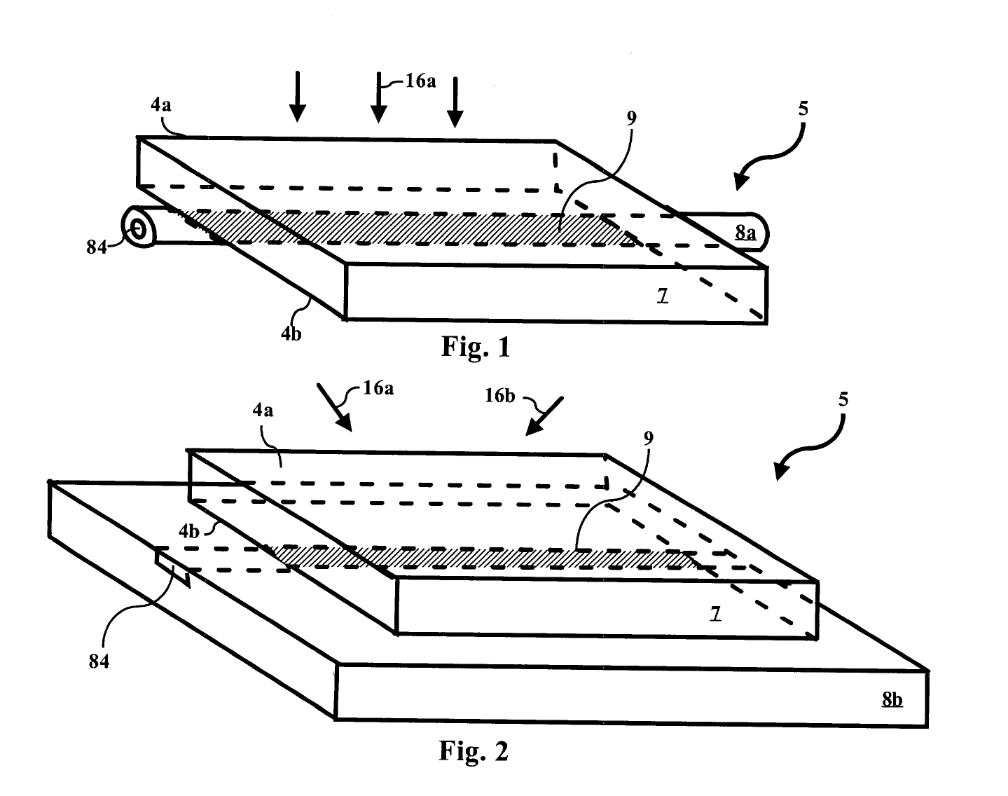

It will be readily understood that the components of the present invention, as generally described and illustrated in the Figures herein, could be arranged and designed in a wide variety of different configurations. Thus, the following more detailed description of the embodiments of the system and method of the present invention, as represented in FIGS. 1 through 29, is not intended to limit the scope of the invention. The scope of the invention is as broad as claimed herein. The illustrations are merely representative of certain, presently preferred embodiments of the invention. Those presently preferred embodiments of the invention will be best understood by reference to the drawings, wherein like parts are designated by like numerals throughout.

The following description of the Figures is intended only by way of example, and simply illustrates certain presently preferred embodiments consistent with the invention as claimed. The various figures incorporated herein are for illustrative purposes, and are not necessarily drawn to scale.

Referring to FIG. 1 and FIG. 2, an apparatus 5 or system 5 for inscribing a pattern onto optical media 8 consists of mask 7, media 8, and actinic radiation 16. The inscription procedure is facilitated by incident radiation 16 striking upper surface 4a of mask 7, passing through mask 7 and being modulated thereby before exiting through lower surface 4b and entering optical media 8 having core material 84 characterized by a photosensitivity. Radiation 16 is modulated in some aspect as it passes through mask 7. Actinic interaction of radiation 16 with core 84 alters the refractive index characteristics thereof. Actinic alterations of media 8 may be temporary in one embodiment, and permanent in other preferred embodiments. Determination as to whether an actinic inscription is temporary or permanent depends principally upon the optical media used (8) and the wavelength of the actinic radiation 16. Most available actinicly susceptible optical media 8 are of the permanent inscription type. That region of optical media 8 exposed to actinic radiation becomes media grating 9, or an alternative such device. Mask 7 may be an amplitude mask with one or more slits to alter the amplitude of incident radiation; a variable transmission mask such as that resulting from exposed photographic film having variable density or transmissivity as a function of spatial position. An amplitude mask 7 may have a variable transmissivity as a result of a varying thickness of deposited material such as metallization on one or more surfaces 4.

Mask 7 may be a phase mask, designed to alter the relative phase of various spatially distinct portions of incident beam 16 striking the mask, providing the desired diffraction pattern in the output. The process of exposing an actinically susceptible material to actinic radiation effects a change in the refractive index of the susceptible material, by increasing its value.

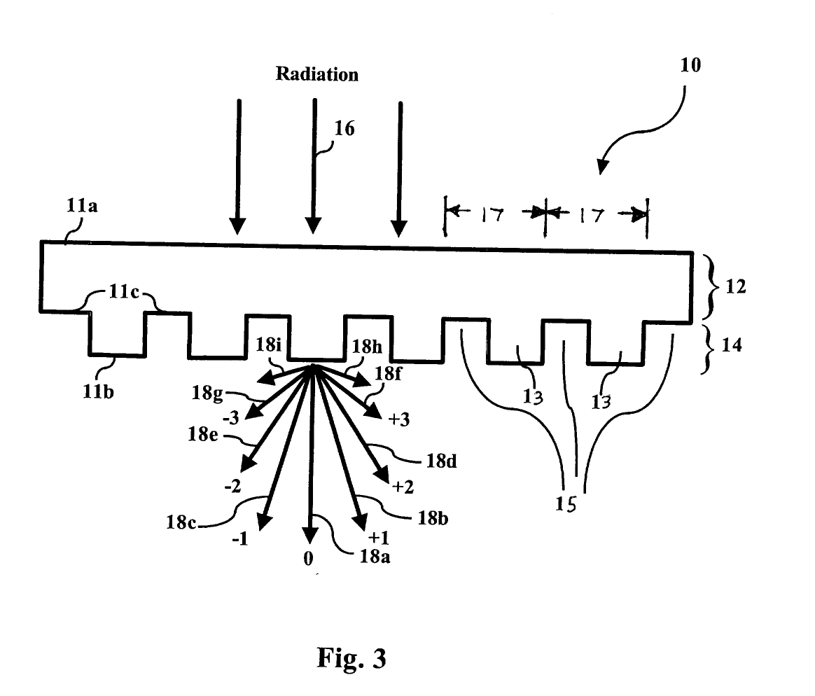

Referring to FIG. 3, relief-type phase mask 10 is composed of substrate 12 and grating 14, with optically-flat upper and lower surfaces 11a and 11b. Grating 14 consists of ridges 13 and slots 15 bounded by upper surface 11c and lower surface 11b. The figure is illustrative only and not drawn to scale. Radiation 16 is incident on optically-flat surface 11a of relief-type phase mask 10 as a uniform plane wave in the instance shown, and is diffracted by grating 14 into diffraction orders 18. Diffracted orders 18 are respectively, the zero order 18a, the +1 and −1 orders, 18b and 18c, the +2 and −2 orders, 18d and 18e, the +3 and −3 orders, 18f and 18g. Grating 14 is composed of two parts, ridges 13 and slots 15. Ridges 13 and slots 15 may vary in size and shape. Dimensional and shape variations of grating 14 and the angle at which incident radiation 16 strikes mask 10 all affect the relative amplitudes of diffraction orders 18, and which orders 18 can exist for the given geometry. For example, for radiation 16 striking mask 10 having a square grating 14 at normal incidence, “even” diffraction orders 2,4,6, . . . are not produced. Spacing 17 of ridges 13, and the number of ridges per wavelength affect which wavelengths are diffracted and how intense the diffracted orders 18 are. Axes 19 define a coordinate system axis relative to phase mask 10. The x, y, and z axes are represented by 19a, 19b, and 19c, respectively. The z axis 19c is the longitudinal axis relative to relief-type phase mask 10. Relief mask 10 can be formed by one of several methods known in the art.

One approach begins with an optically-flat fused silica blank substrate 12 that is subsequently coated with an actinicly susceptible photoresist material and exposed to actinic radiation through an amplitude mask pattern. Parts of substrate 12 are exposed to radiation 16, and parts remain either unexposed or are less intensely exposed, according to the spatial pattern imposed on the photoresist surface. After exposure, the photoresist is chemically etched leaving a grating pattern 14 on mask substrate 12.

An alternate approach involves forming a metallized amplitude mask pattern on substrate 12 and subsequently using RIE (reactive ion etching) to produce grating structure 14 having ridges 13 and slots 15.

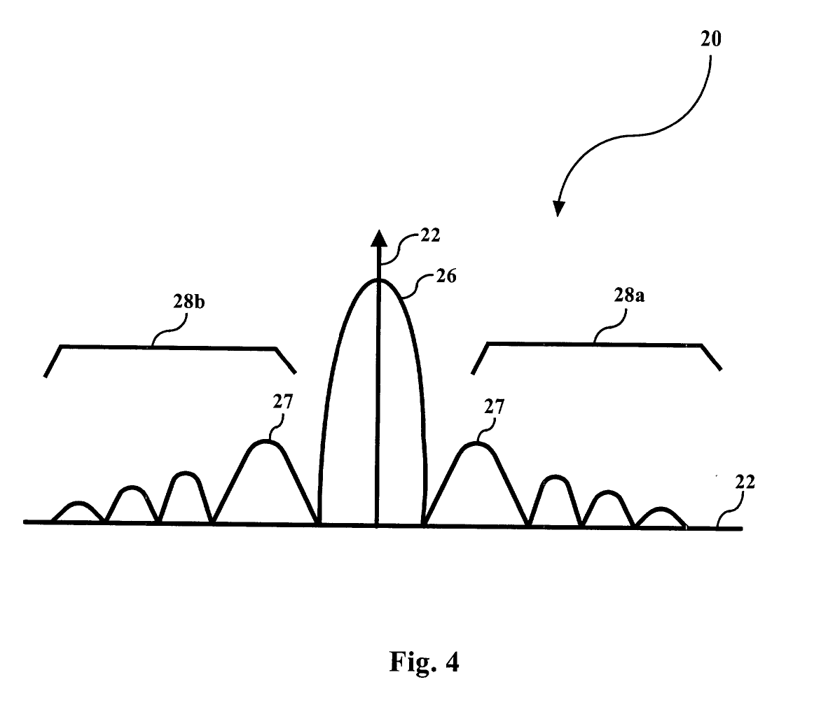

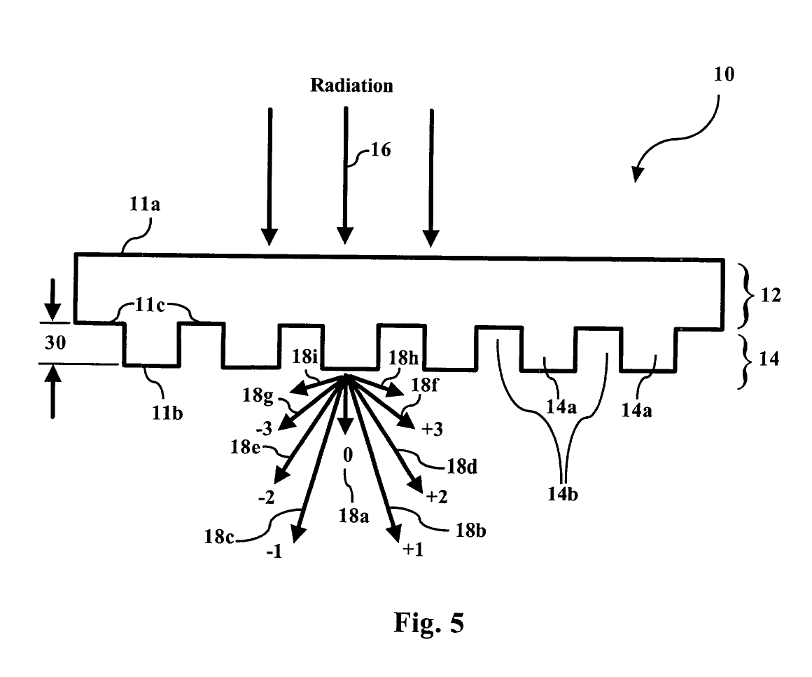

Referring to FIG. 4, spatial profile 20 of mask diffraction orders 18 is shown as a function of position 22 and amplitude 24. The result of radiation being diffracted through relief-type phase mask 10 is to produce spatial profile 20 whose amplitude varies as a function of position. Multiple lobes are produced, including main lobe 26, side lobes 28, and principal side lobes 27. Much of the work of optimizing phase mask characteristics involves altering the relative magnitudes of the various lobes—the main lobe 26 and side lobes 28 of the given diffraction pattern Referring to FIG. 5, phase mask 10 has grating 14, ridges 13, slots 15, spacing 17, and ridge depth 30, all of which can be set based on design considerations. Ridge depth 30 can be set to minimize one of the diffraction orders 18 otherwise present. Ridge depth 30 is most often designed to minimize the amplitude of the main lobe 18a of diffraction orders 18 by setting it equal to one quarter wavelength of the optical wavelength at which the mask is to be used. A judicious choice of ridge depth 30 can minimize the magnitude of one diffraction order 18 only at a single wavelength. Reduction of competing or undesired orders 18 is a major obstacle in the design and usage of relief-type phase masks. Even if the relief structure 14 of phase mask 10 were filled with a dissimilar dielectric to produce a periodic arrangement, undesired diffraction orders are still produced. Two beams are used to interferometrically produce a grating pattern by passing actinic radiation through phase mask 10 onto an actinicly susceptible optical media 8, such as a fiber. The two largest magnitude diffraction order components remaining after one diffraction order is minimized may be used interferometrically to produce the actinic modulation in optical media 8.

The resultant structure has a narrow wavelength range of useful operation. It can only be used effectively at a single wavelength in order to achieve minimization of the designated order that is selected to be minimized. The relief-type phase mask is wavelength sensitive at the design frequency. It is designed to be optimal for one wavelength only. Wavelengths used to write the mask are ordinarily not in the same range as the wavelengths at which the mask is used to expose other optical media 8. A mask 10 may be written in the far UV (ultraviolet) whereas it may be used in other wavelength ranges such as the visible or infrared (IR) wavelength regions to actinicly expose optical fibers or waveguide devices.

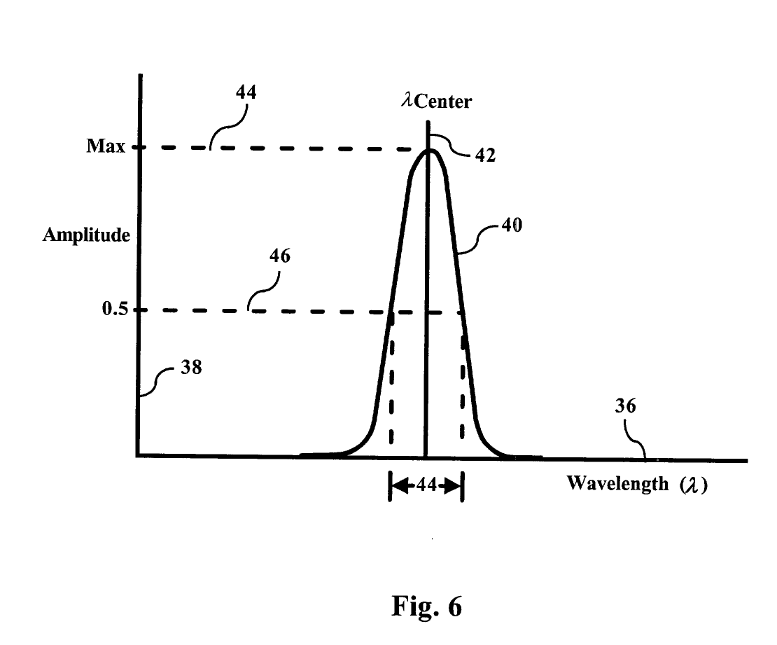

Referring to FIG. 6, profile 40 for relief-type phase mask10 is a function of wavelength 36 and amplitude 38. Profile 40 is characterized by center wavelength 42, peak amplitude 46, and amplitude 48 and usable wavelength range 44. Region 44 shows the wavelength range over which the relief-type mask 10 may be used. Central wavelength 42 is the wavelength at which the mask is designed to be used and at which optimum results are expected. The maximumusable wavelength range of a relief-type phase mask is around 7-10 nanometers. The usable range is very narrow. Attempts to use the mask beyond a very narrow wavelength range result in additional problematic degradations, particularly from unwanted diffraction orders. A relief-type phase mask10 may be fabricated, but it is typically only usable at a single wavelength, or very narrow wavelength band around the design wavelength. Attempting to use the mask at a wavelength different from the design wavelength produces unwanted diffraction orders and results in increased background light and poor resolution in the final product, optical media 8. The physical geometry design of ridge depth 30 and grating 14 is intimately connected to the production of one or more unwanted diffraction orders. Changing ridge depth 30 can adversely affect the magnitude of unwanted diffraction orders.

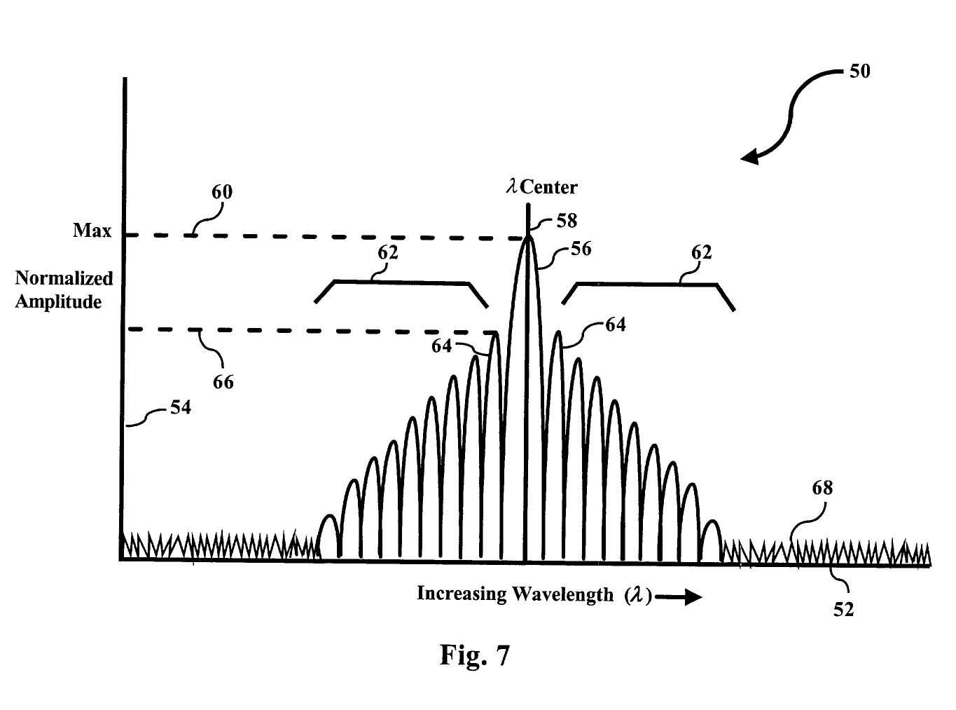

Referring to FIG. 7, optical media 8 after actinic exposure through relief-type phase mask 10 has filter profile 50 shown relative to wavelength axis 52 and amplitude axis 54. Filter profile 50 is characterized by main lobe 56, center wavelength 58, maximum amplitude 60, and side lobes 62. The principal side lobes 64 are those closest in wavelength to main lobe 56 and typically have the largest amplitude of any of side lobes 62. A background amplitude or noise level 68 is always present, in conjunction with the main lobe 56 and side lobes 62.

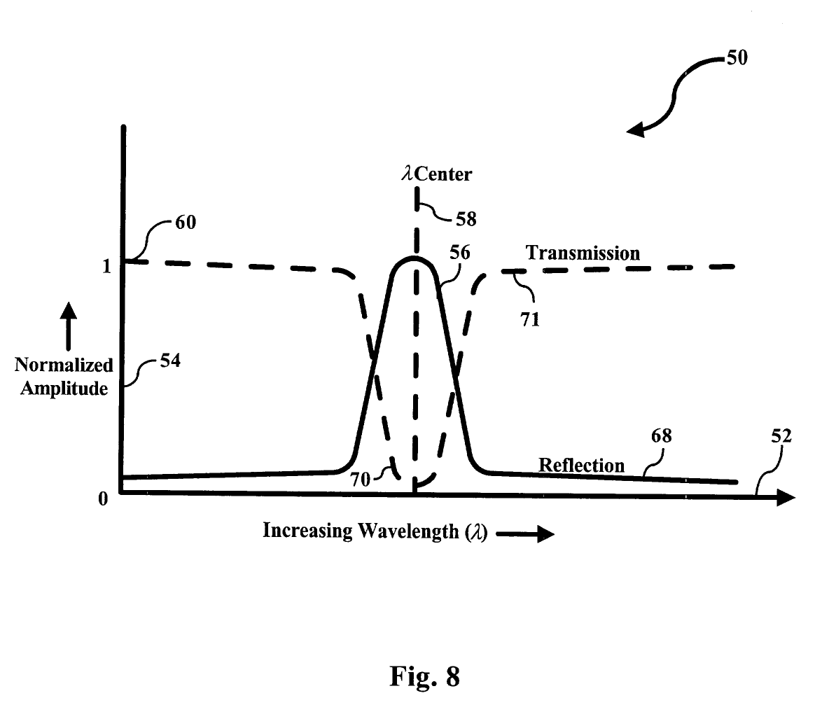

Referring to FIG. 8 specifically, and FIGS. 1 through 8 generally, filter profile 50 for an idealized narrow band Bragg structure may be characterized by the main lobe of a reflection profile 56 or the main lobe of a transmission profile 70 in conjunction with common center wavelength 58, and respective background levels 68 and 71, providing absorption losses are sufficiently low. Profile 50 in FIG. 8 is idealized in the sense that background levels 68 and 71 are smooth, lacking side lobes, and otherwise featureless. Ordinarily, Bragg structures 8 produce undesired side lobes that reduce the usable range of the device. Principal side lobes 64 resulting from unwanted diffraction orders 18 reduce the effective isolation obtainable between successive wavelength channels. Energy from unwanted phase-mask diffraction orders limits the quality and resolution obtainable with devices made under such circumstances.

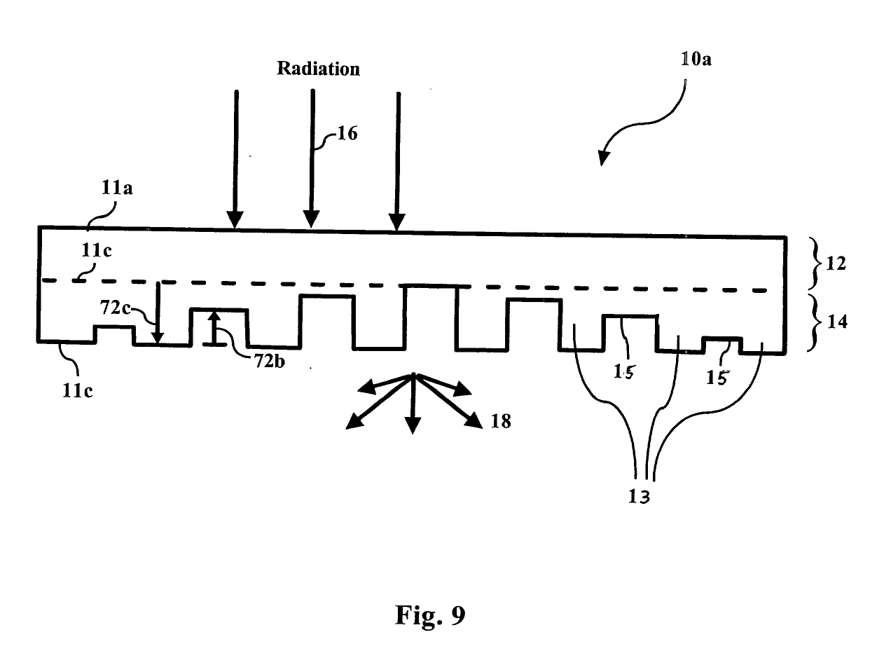

Referring to FIG. 9 specifically, while generally referring to FIGS. 1 through 9, relief-type phase mask 10a may be fabricated with an apodization profile imposed thereon by varying the ridge 13 and slot 15 dimensions. The embodiment shown has variable slot depth 72b and constant ridge height 72c. Another variant may have variable ridge height 72c and constant slot depth 72b, in order to provide varying diffraction efficiency along the phase mask. Any variation in the relative depth of slots 15 and ridges 13 affects the magnitude of diffraction orders 18.

However, the apodization of a ridge-type mask 10 using variation of grating depth compromises the minimization of the zero order and higher orders of diffraction. Increased diffraction orders 18 are produced with the compromise in varying grating depth 72b, 72c. The result is compromised performance.

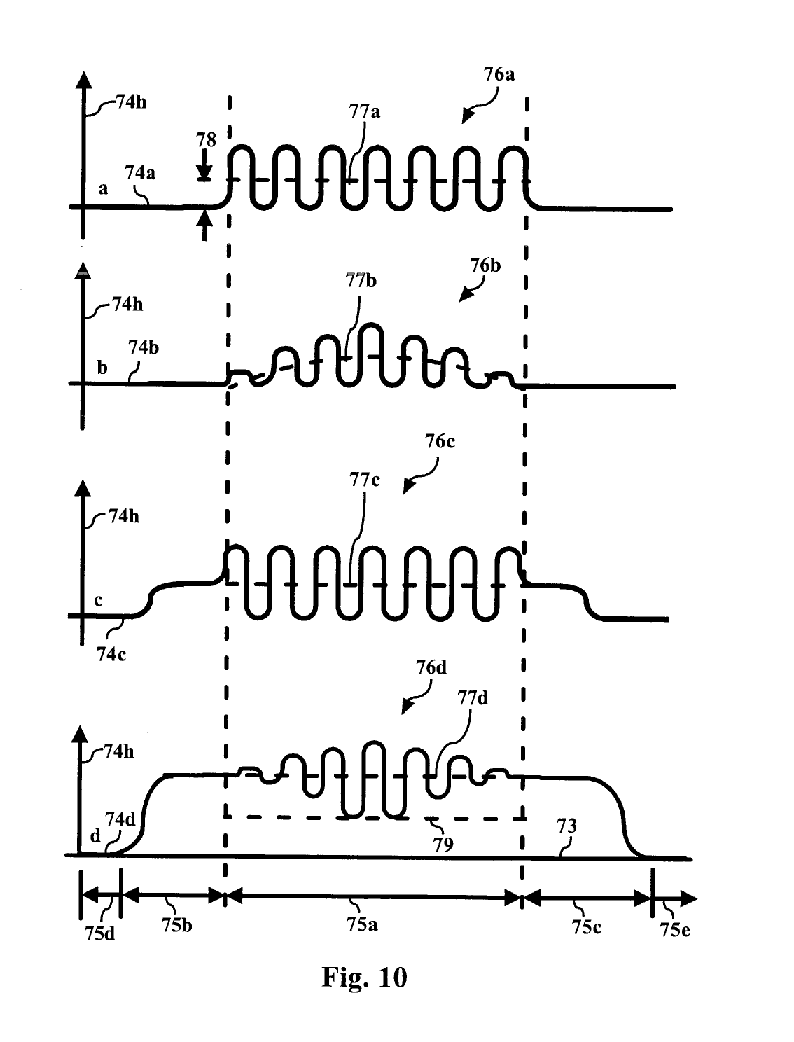

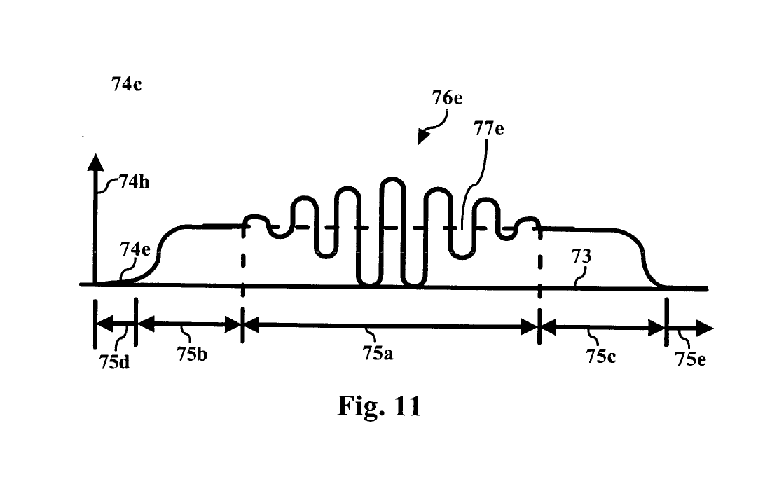

Referring to FIG. 10 and FIG. 11 specifically, while referring generally to FIGS. 1 through 11, refractive index profile 76 of actinically exposed core 84 is given as a function of position 73 along optical media 8, and refractive index 74h. Index 74 may be referred to as index, refractive index, refractive index magnitude, and core index. Core 84 is the optically transmissive central portion of optical waveguide media 8. Planar media 8b and optical fiber media 8a are examples of media having core 84 and core refractive index 74. Index profile features 76 are shown relative to unexposed core refractive index 74a, 74b, 74c, 74d. Range 75a is actinicly exposed grating region. For FIGS. 9b and 9c, ranges 75b, and 75c represent additional longitudinal extent of actinic exposure for FIGS. 9c and 9d. Ranges 75d and 75e show unexposed core regions 84 of optical media 8.

Profiles 76a, 76b, 76c, and 76d represent the refractive index variation patterns of grating 9, resulting from actinicly exposed media 8 using various optical masking conditions. Profile 76a results from actinic exposure using relief-type phase mask 10 without any apodization. The average refractive index 77a of profile 76a is offset 78 from core index 74a. The index mismatch between core media 82 and grating 9 is a source of signal degradation. Offset 78 is undesirable because it lowers optical transmission, increases reflections, potentially causes unwanted system resonances, and increases system noise. Profile 76b results from actinic exposure using relief-type phase mask 10 with an added apodization masking step. Average refractive index 77b is nonzero, but improved over the non-apodized case. Index offset is still present, but of lesser magnitude. Lower optical transmission, increased reflection, unwanted system resonances, and increased system noise are still concerns, but reduced in magnitude from that of a non-apodized relief-type phase mask exposure. Changes in the average refractive index 77b in the range of the grating 76b result in an undesired chirping effect. It is best to avoid such effects. Profiles 76c and 76d result from actinic exposure using a phase mask 10 and a multi-step exposure process to adjust the average refractive core index 77c of grating 9 and reduce the refractive index mismatch 78. Profile 76c is not apodized while profile 76d is.

An undesired effect arising from multiple actinic exposures is shown in profile 76d. In an attempt to compensate for one undesirable effect, another is introduced. The multi-step exposure process involves exposing actinicly-susceptible media 8 twice, once to inscribe the grating pattern and a second time to normalize the average refractive index across the grating. A problem arises because adjusting the index offset typically results in a diminution of the depth of modulation (sometimes called the visibility factor) of the desired grating profile relative to the total index change of the fiber core. Reduced grating reflectivity at the desired Bragg reflection center wavelength occurs because of the diminution of the peak-to-peak amplitude of apodized grating profile 76d. Minimum apodization profile level 79a is offset from core index 73 by index difference 79d. The lower boundary 79a of apodization profile 76d is separated from core index 73 by index difference 79b. Proposals to perform multi-step actinic exposures using complementary amplitude exposures to compensate for the actinic amplitude disparity have their own set of problems. Such problems include the requirement of multiple exposures and the difficulty of obtaining complimentarity in the masked results, which consequently increases the complexity, process time, and cost of production while diminishing its desirability.

Referring to FIG. 11, profile 76erepresents an ideal core refractive index profile having grating apodization without having changes in the average refractive index 77e over the range of the grating 75a, fabricated according to one embodiment of the invention.

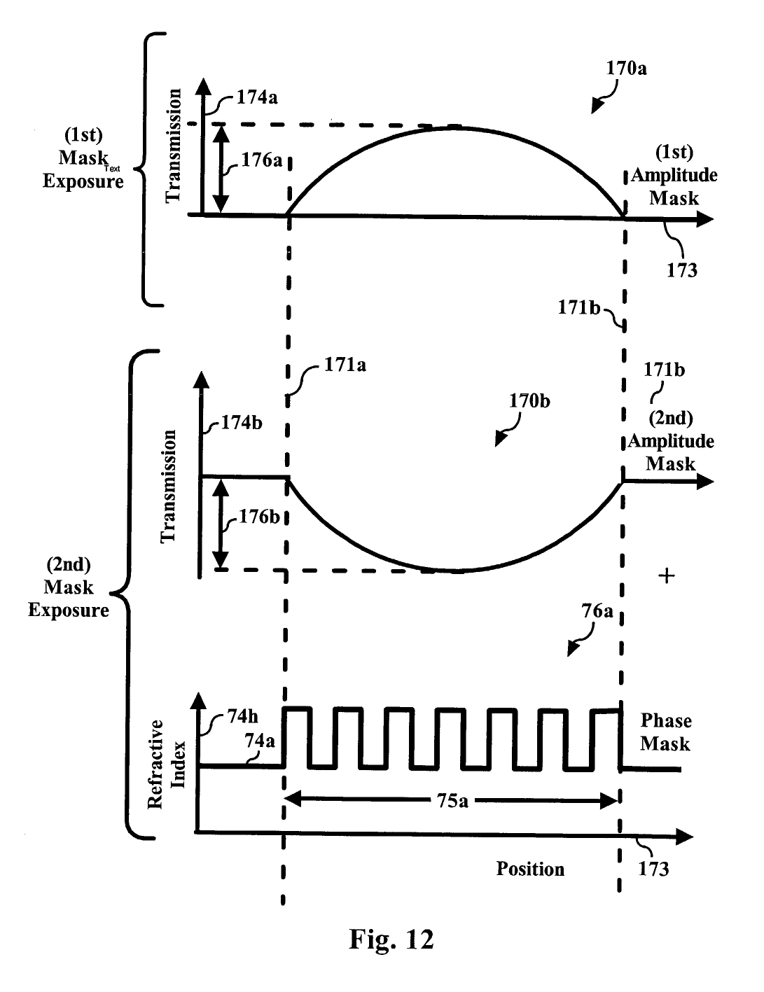

Referring to FIG. 12 specifically, while referring generally to FIGS. 1 through 12, the multi-step masking process to produce apodized gratings with reduced core refractive index offset 78 using relief-type phase mask 10 requires at least three masks—two complimentary amplitude masks 7a, 7b, and a phase mask 10. A first amplitude mask 7a characterized by peak amplitude 176a has transmission profile 170a shown as a function of position 173 and transmission 174a. A second amplitude mask 7b, complementary in amplitude profile to mask 7a, is characterized by peak amplitude 176b and has transmission profile 170b shown as a function of position 173 and transmission 174b. Both amplitude masks have longitudinal extent characterized by range 75a, beginning at starting point 171a and extending through ending point 171b. The third mask—a relief-type phase mask 10, has refractive index profile 76a shown as a function of position 173 and refractive index 74h. The first mask exposure step of the multi-step exposure process involving relief-type phase masks uses mask 7a to expose optical media 8, fiber or waveguide media 8 and offset the average local refractive index value. The second mask exposure step involves using complementary amplitude mask 7b and phase mask 10, simultaneously to induce the apodized grating structure into optical media 8. The multi-step process requires additional mask generation. Masks can be reused. For production purposes a more restrictive requirement of the process is optical alignment and registration at each masking stage. The increased demands limit cost-effectiveness of the procedure.

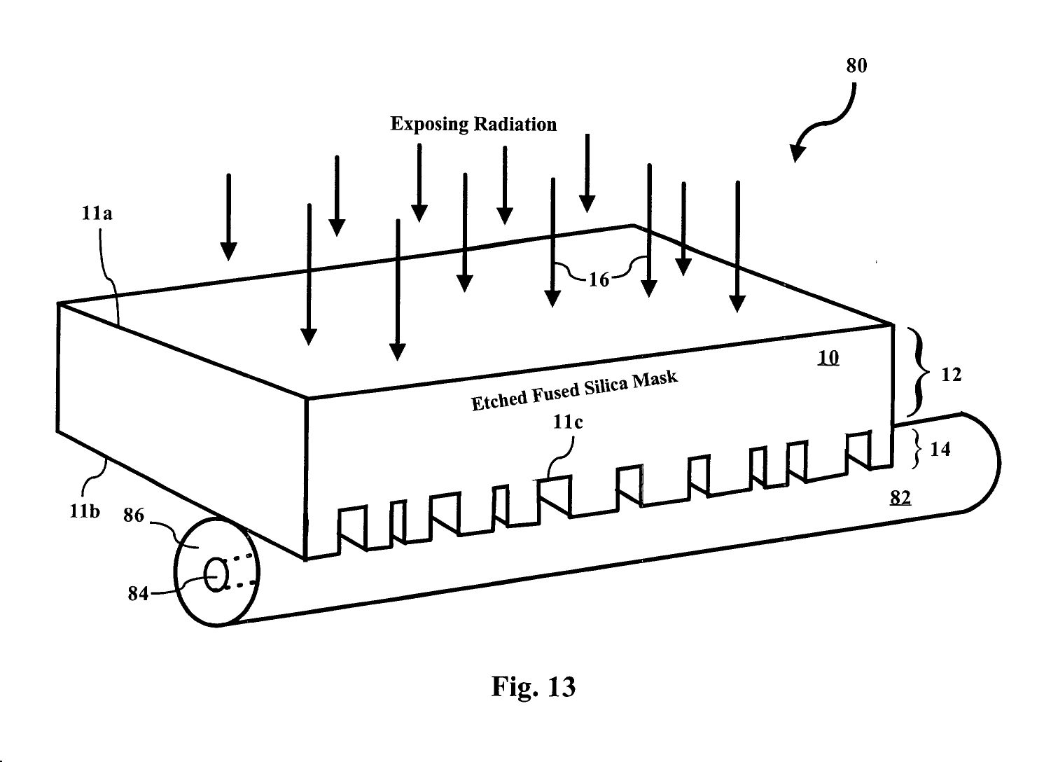

Referring to FIG. 13, apparatus 80 for exposing optical media has normally incident actinic radiation 16 passing through relief-type phase mask 10, cladding 86, and core 84 of optical fiber 82. Optical fiber 82 before exposure is optically transparent optical fiber. After actinic exposure optical fiber 82 becomes fiber Bragg grating 82. Phase mask 10 is a specific embodiment of generic mask 7 discussed previously. Fiber 82 is a specific embodiment of generic optical media 8 mentioned earlier.

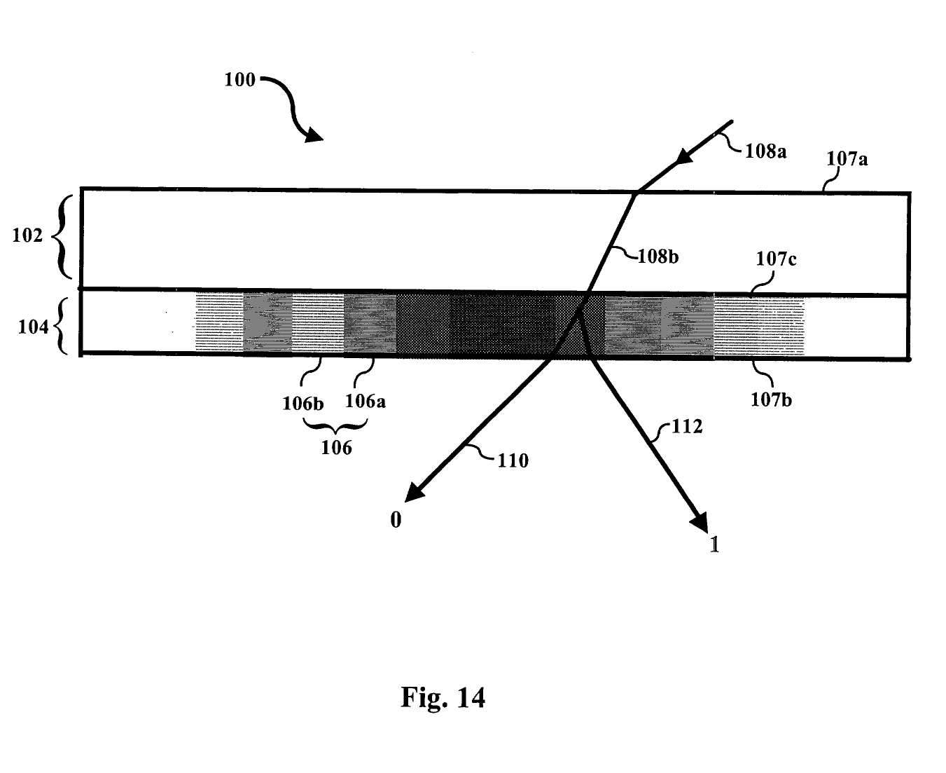

Referring to FIG. 14, volume hologram phase mask 100, according to the invention, consists of substrate 102, and holographic media 104. If incident radiation 108a strikes phase mask 100 at normal incidence, or near normal incidence the structure functions as a “Raman-Nath” (also called “Debye-Sears”) type diffraction grating and produces multiple undesired diffraction orders, essentially the same as relief-type phase mask 10. If incident radiation 108a is arranged to strike mask 100 at an angle of incidence sufficiently different from normal incidence, then Bragg-type reflections are produced in accordance with the invention. Holographic media 104, is composed of representative volumetric elements 106. Each volumetric element consists of microscopic holographic patterns dispersed throughout the volumetric element 106. Cumulatively, holographic elements 106 can perform the function of a Bragg grating on incident radiation 108 to produce exactly two diffraction orders. Volumetric elements 106a and 106b symbolically represent the cumulative effect of periodic microscopic regions of dissimilar refractive index. The volume hologram phase mask light-directing structure consists of refractive index changes spread throughout the volume on a microscopic scale. The diffraction orders produced are the “zero” order 110 and the “first” order 112. By proper design, the two diffraction order amplitudes can be adjusted to be essentially equal in one preferred embodiment of the invention. Other amplitude ratios between the two diffraction-order magnitudes are also possible, and in accordance with the invention.

Radiation 108 is incident on surface 107a at non-normal incidence relative to surface 107a. Radiation 108a enters substrate 12 and becomes 108b. Radiation 108b passes through substrate102 and is subsequently diffracted by volumetric holographic media 104 into two diffraction orders 110 and 112. Using radiation 108 at non-normal incidence, the volumetric hologram phase mask can be arranged to produce exactly two diffraction orders of essentially equal magnitude. Only the 0 and 1 diffraction orders exist. Which diffraction orders are used is irrelevant. The relative magnitudes of the diffraction orders used are critical. The presence of any unwanted diffraction orders reduces the obtainable quality of devices fabricated. Parameters such as channel isolation and the maximum obtainable filter slope are affected adversely by unwanted diffraction orders. Desirable properties for holographic media 104 include: 1. Reasonable transparency to the optical radiation used, 2. Actinic susceptibility, 3. Conformability of shape.

Substrate 102 can be any material that is: 1. Reasonably transparent to the optical radiation used, 2. Compatible with holographic media 104, 3. Able to provide adequate mechanical support for holographic media 104. Optical flatness of substrate 102 is not required, which reduces the cost of substrate material dramatically over that required by conventional relief-type masks. Ordinary glass is satisfactory as a substrate material, thus eliminating the expense of using optically flat fused silica and the like. Silica substrates can be used, but are not required. An alternate embodiment has the holographic media 104 and support structure 102 integrated into the same volumetric space. One embodiment of the invention includes macroscopic integration of 102 and 104, while an alternate embodiment of the invention includes microscopic integration. Another preferred embodiment according to the invention uses at least one additional layer to seal the holographic media 104 from exposure to external media and potentially deleterious environmental constituents. Suitable substrate materials include but are not limited to: ordinary glass, silica, plastic, and polymers.

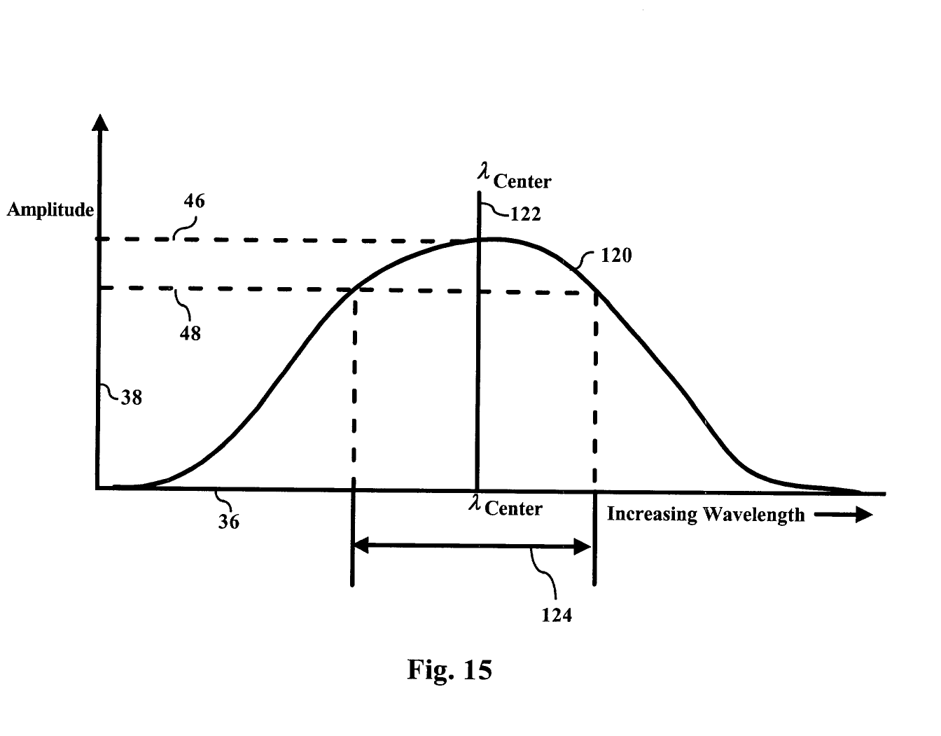

Referring to FIG. 15, profile 120 of volume hologram phase mask 100 is characterized by center wavelength 122, range 124, and peak amplitude 46, shown as a function of wavelength 36 and amplitude 38. A volume hologram phase mask 100 fabricated according to the invention has a usable continuous wavelength range on the order of 100 nanometers, as compared to the maximum usable wavelength range of a relief-type phase mask on the order of 5-10 nanometers. Wavelength range 124 does not rely upon discrete harmonics of a grating periodicity to be usable. Phase mask 100 according to the invention has a usable wavelength range ten times larger than that obtainable using conventional relief-type phase masks 10. A relief-type mask 10 is only usable over a very narrow wavelength range 44, essentially at a single design wavelength. The increased operational wavelength range 124 provided by the invention enables the fabrication of Bragg gratings and other devices designed to operate over a significant band of frequencies all fabricated using the same phase mask 100. A tunable source or, alternatively, multiple sources of disparate wavelength can be used to provide the requisite radiation over the usable wavelength range of the mask. A phase mask 100 fabricated according to the invention increases the phase mask functionality while simultaneously reducing the cost required to produce multiple closely spaced devices and diffractive structures such as waveguide couplers, multiplexors, demultiplexors, waveguide reflectors, fiber Bragg gratings, planar structures, filters, and the like. Devices fabricated according to the invention can also be used over a similar wavelength range of at least 100 nanometers, providing the concomitant optical design correctly accounts for the various wavelengths employed. When discussing a volume hologram phase mask and mention is made of a “fiber Bragg grating” it needs to be recognized that in essentially all instances “planar” and “waveguide” structures are interchangable therewith. The various options of fiber, planar integrated optical circuits, and other waveguiding structures are used essentially synonymously. Structural differences for the present purposes may involve minor variations without substantive changes of the invention. For purposes of discussion and illustration, fibers are used most frequently, as they can help illustrate many of the anticipated features of the invention in a most lucid fashion. Use of the present invention in the context of optical planar integrated waveguide architectures involving passive and active media is one of the embodiments encompassed herein.

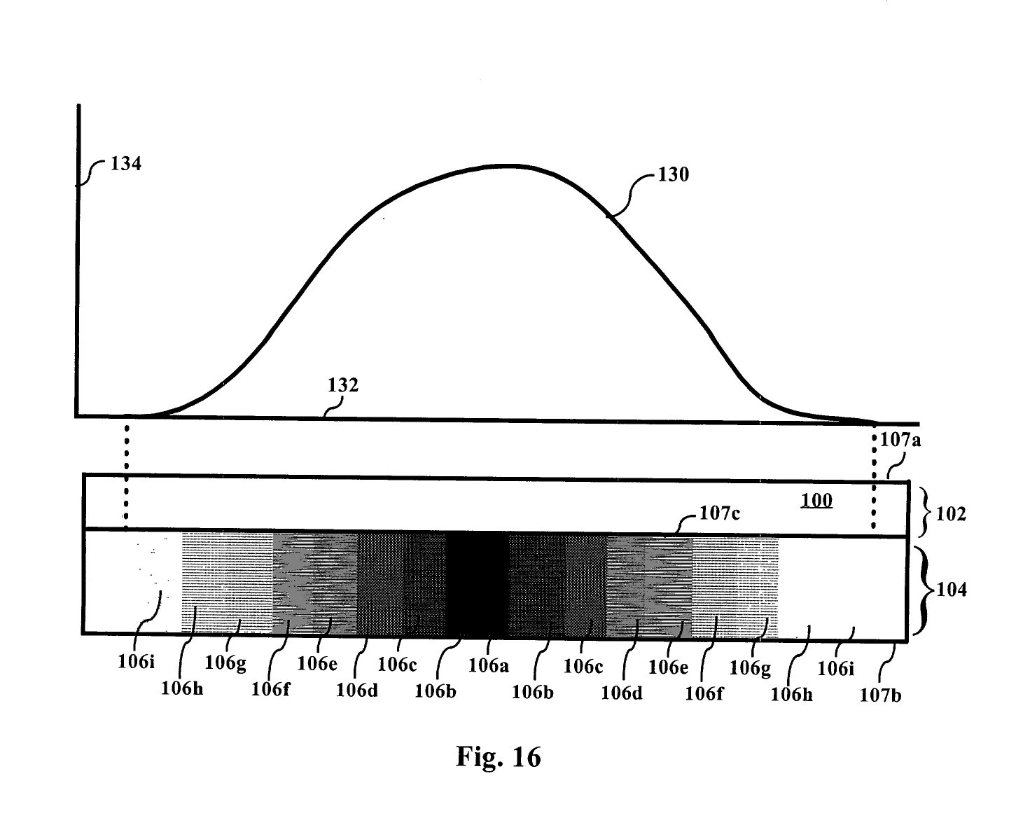

Referring to FIG. 16, apodization profile 130 is shown as a quasi-gaussian amplitude pattern, as a function of position 132 and diffraction efficiency 134. Other apodization profiles are possible and easily formulated in accordance with the invention. One embodiment of the invention has volume hologram phase mask 100 with an apodization profile of diffraction efficiency 130 intrinsically incorporated therein. In accordance with the invention, volumetric elements 106 entail variations in diffraction efficiency 134 as a function of longitudinal position 132. in the mask. Incorporation of Bragg structures and spatial variation in diffraction efficiency, intrinsically in volume hologram phase mask 100 enables the production of high quality devices having high resolution, any predetermined spectral response, excellent channel isolation, and if desired, extremely narrow bandwidths. The result is devices of markedly improved performance with a cost of materials and a cost of manufacture more than an order of magnitude lower than conventional methods.

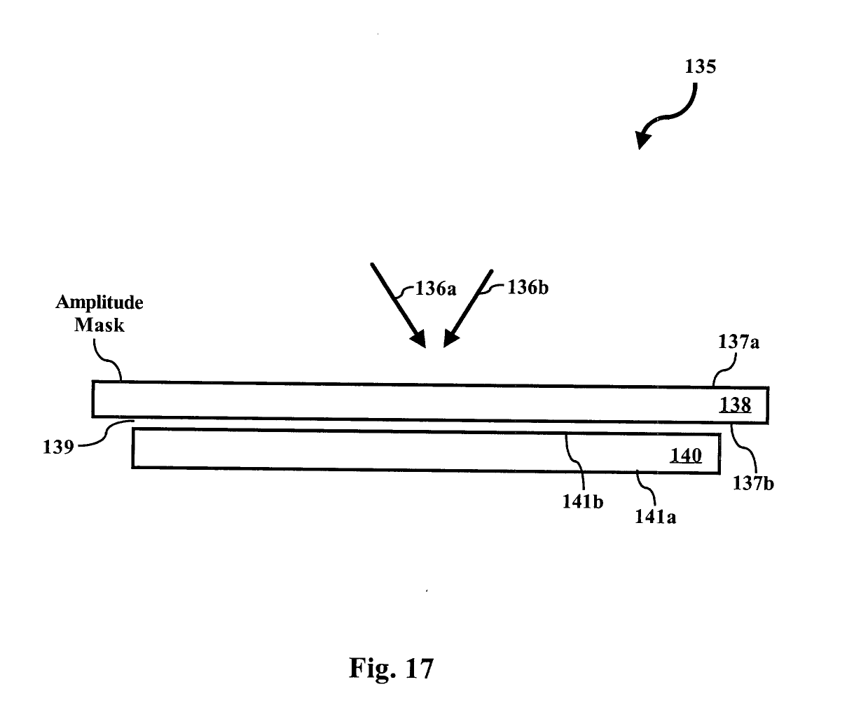

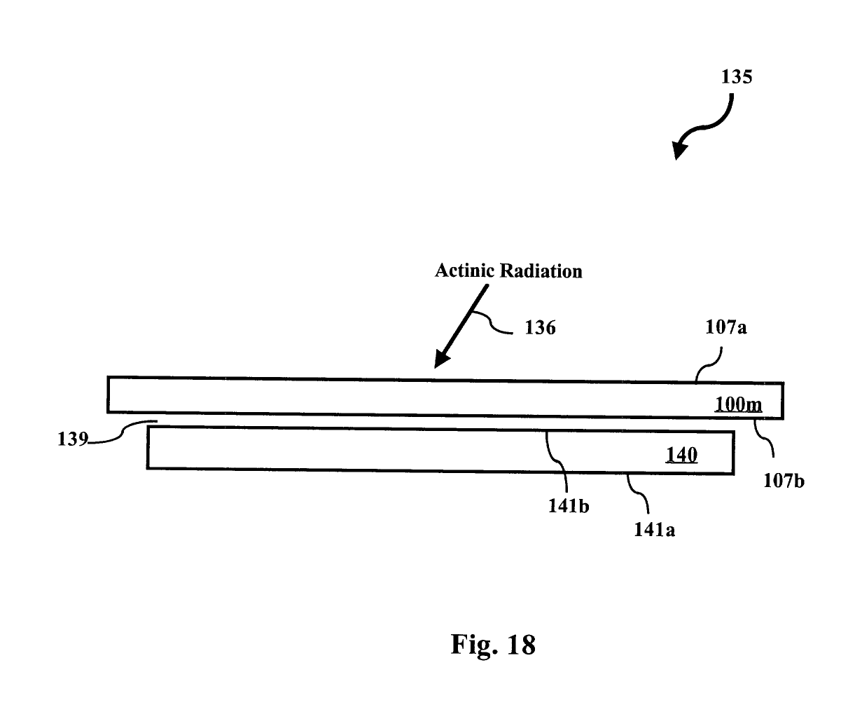

Referring to FIG. 17 and FIG. 18, apparatus 135 for writing apodized phase masks uses actinic radiation 136 in conjunction with an apodization mask 138, 100m to expose or “write” apodization information into Holographic material 140 which, upon completion, becomes an apodized volume hologram phase mask 100 according to the invention. Actinic radiation beams 136a and 136b pass through surface 137a, through the amplitude modulating media of amplitude mask 138, and out surface 137b. Radiation 136 continues through interstitial space 139 and surface 141b to enter actinicly susceptible holographic media 140, where it interacts therewith to generate volume phase hologram phase mask 100 containing both the desired mask structure and the apodization information derived from passage through amplitude mask 138. In a preferred embodiment interstitial space 139 between the apodization mask 138, 100 and the holographic media 140 is substantially zero, yielding a substantially “contact print” type of exposure. Actinic beams 136a and 136b are coherent in a preferred embodiment of the invention. One embodiment of amplitude mask 138 uses variable transmissivity material such as photographic media with density variations spatially distributed across its surface. Alternatively, variation in a metallization thickness across the spatial extent of amplitude mask 138 is used to produce the amplitude modulation. Amplitude modulation of the incident actinic radiation 136 by amplitude mask 138 results in changes in diffraction efficiency as a function of spatial position in holographic media 140, and consequently yields “apodization” in the resultant volume hologram phase mask 100.

Referring to FIG. 18, radiation 136 passes through apodized volume hologram phase mask 100m to interact actinicly with holographic media 140 and produce an apodized volume hologram phase mask 100, thus providing a copy of the phase mask. Interstitial space 139 is nominally zero in a preferred embodiment.

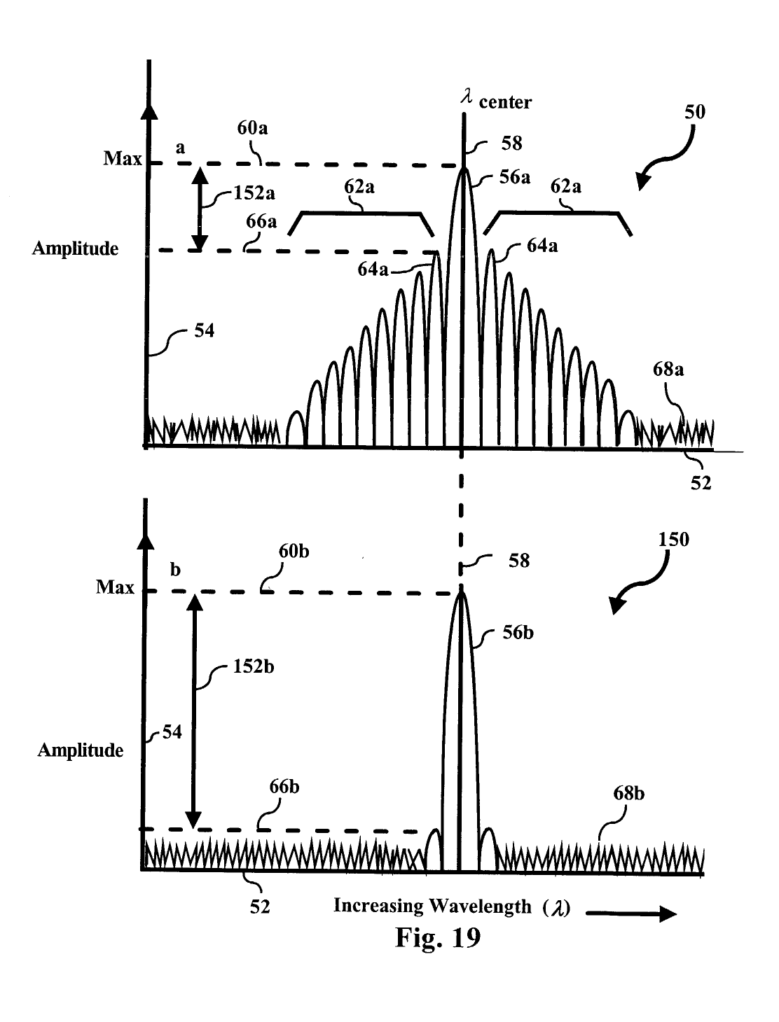

Referring to FIG. 19, filter profile 50 for Bragg grating 82 fabricated using a conventional relief-type phase mask 10 has channel isolation 152a. Channel isolation 152 is the amplitude difference between the desired main lobe wavelength peak 60 and the peak amplitude of the undesired nearby side lobes 66. The terms isolation, or channel isolation, are used because the amplitude difference is what limits how closely two adjacent channels can be placed in a multi-channel system before mutual interference precludes adequate channel discrimination by the system. Filter profile 150 for a Bragg grating 82 fabricated according to the invention using apodized volume hologram phase mask 100, also according to the invention, has channel isolation 152b.

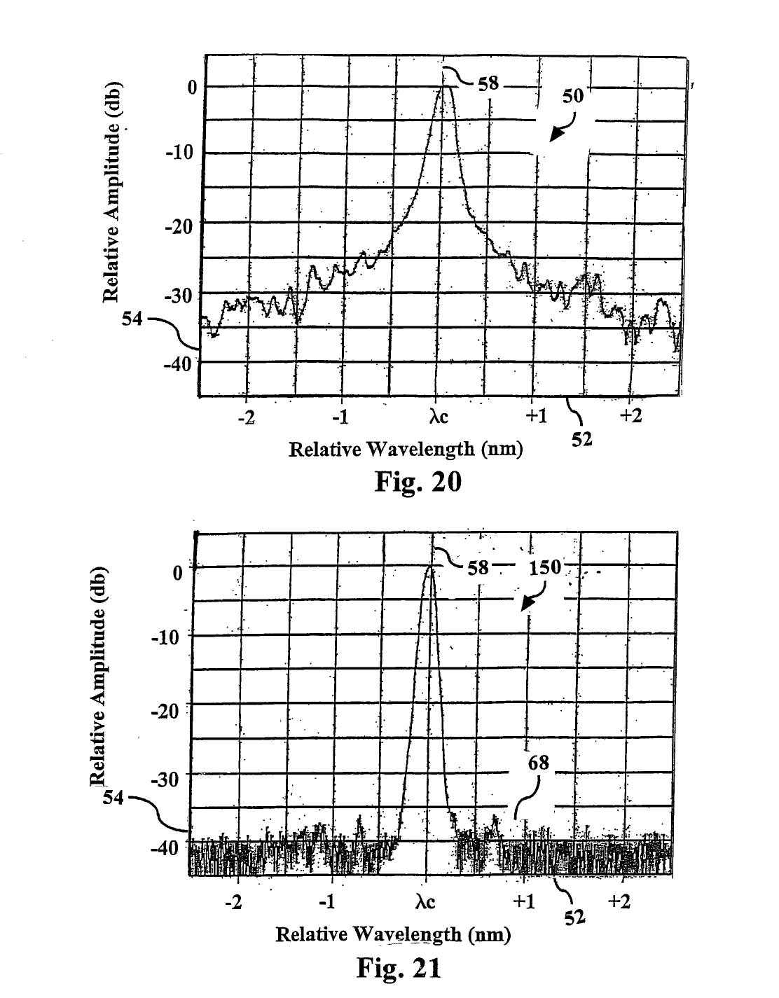

Referring to FIG. 20 specifically, while referring generally to FIGS. 1 through 20, filter profile 50 is the measured profile data, for a fiber Bragg grating 82 made using a phase mask without apodization and plotted as a function of relative wavelength 52 and amplitude 54. As can be seen, the filter exhibits poor channel isolation 152 and bandwidth characteristics.

Referring to FIG. 21, filter profile 150 is measured data, for a fiber Bragg grating 82 made in accordance with the invention using an apodized volume hologram phase mask 100, also according to the invention. The measured data is plotted as a function of normalized wavelength 52 and amplitude 54. The filter profile 150 has a narrow bandwidth, by design, and excellent isolation—down to the level of the system background noise 68.

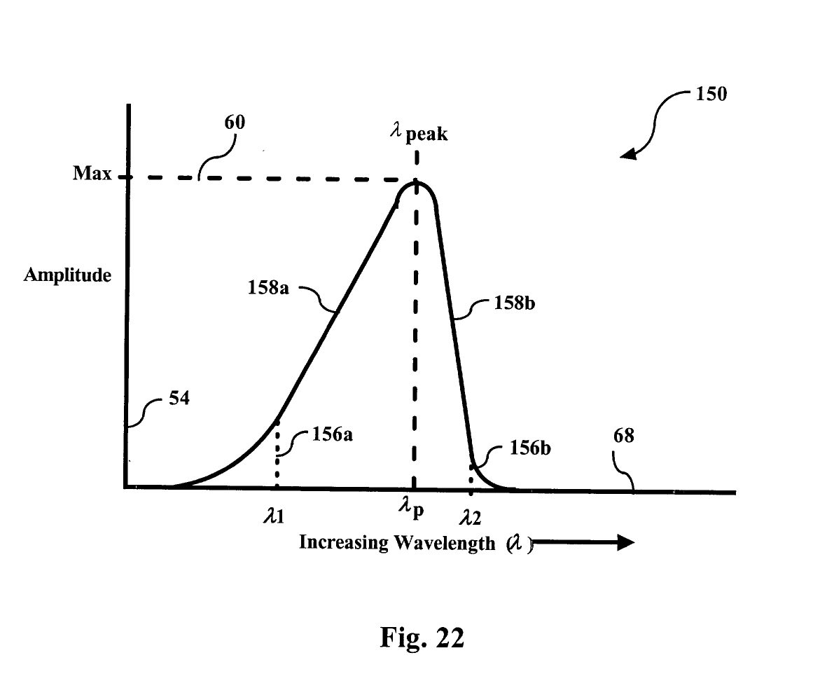

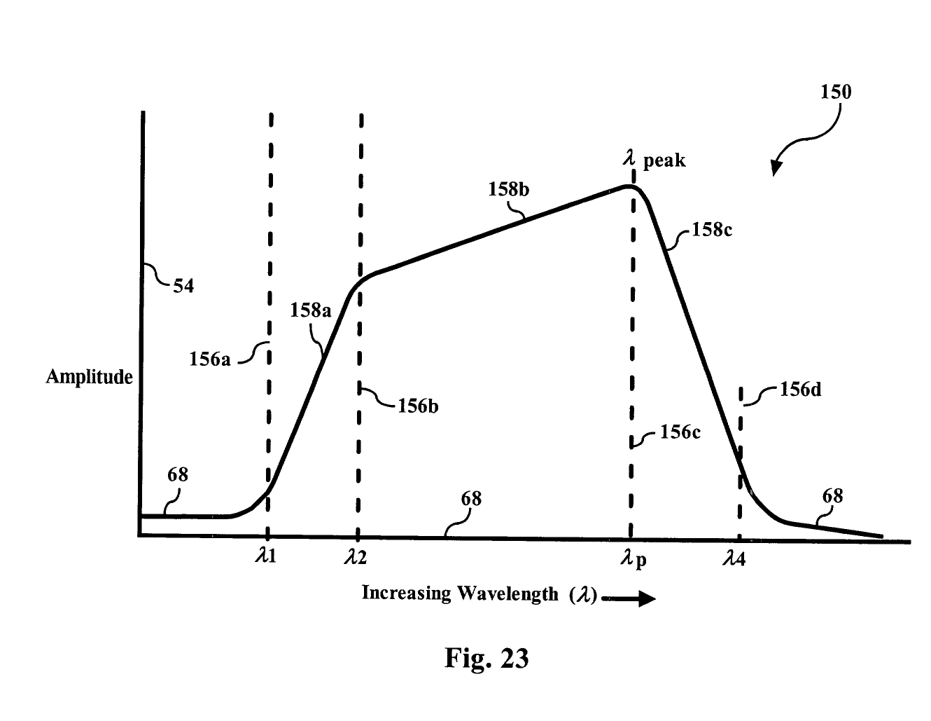

Referring to FIG. 22 and FIG. 23, filter profiles 150 of non-simple filter characteristics are enabled by the present invention. Transition wavelengths 156a, 156b, 156c, and 156d, demarcate distinct filter slope regions 158a,158b, and 158c. Specifying additional transition wavelengths 156 and slope regions 158 in some cases may require multiple filter sections 82 fabricated according to the invention. All types of diffraction structures are possible in planar and fiber embodiments, as enabled by the invention.

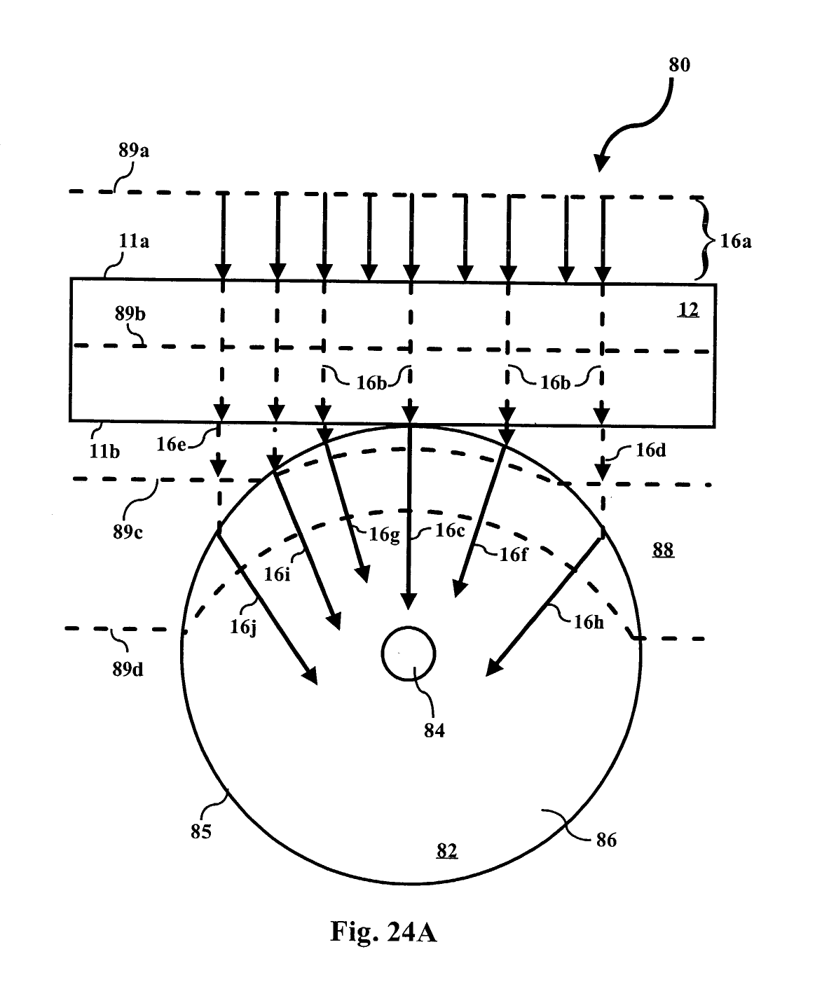

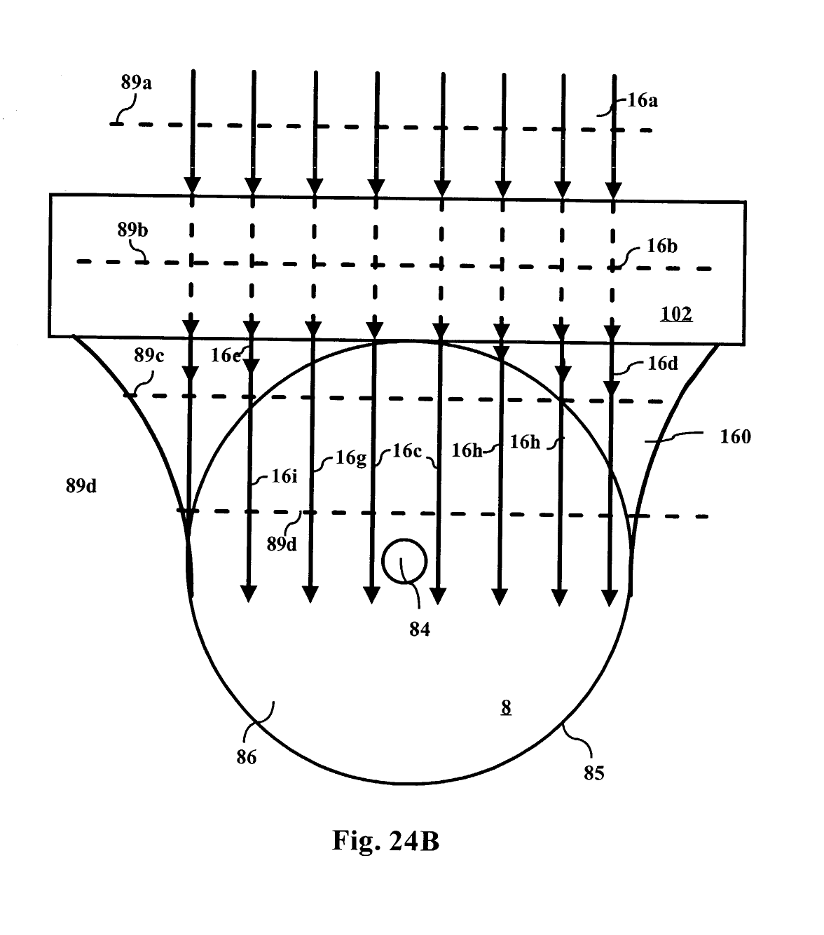

Referring to FIG. 24A, wavefront distortion is illustrated at the phase mask and optic fiber interface. Normally incident actinic radiation 16a begins as a plane wave having planar wavefront 89a, passes into substrate 12 through optically flat surface 11a as radiation 16b, continues with planar wavefront 89b through substrate 12, and exits substrate 12 as a planar wavefront passing through optically flat surface 11b with a direction of travel normal to surface 11b. After exiting substrate 12, the radiation plane wavefront 89b begins to change shape, as portions of radiation 16 traverse disparate paths. Radiation component 16c enters cladding 86 adjacent to surface 11b and continues without changing direction. Radiation components 16d and 16econtinue in the direction normal to surface 11b after they enter media 88, which is air. With the exception of radiation component 16c, all radiation components 16d, 16e, 16f, 16g, 16h, and 16i change direction at interface 87, at which media 88 and fiber cladding 86 meet. Planar wavefront 89b deteriorates to successively become non-planar wavefronts 89c and then 89d. The collective result of altered paths for radiation components 16f, 16g, 16h, 16i, 16j and the concomitant distorted wavefront 89 is that the spatial radiation pattern is changed and the obtainable resolution lowered. The desired optical pattern result tends to be defocused. The defocusing effect is generally secondary in magnitude to the effects of undesired diffraction orders 18d, 18e, 18f, 18g, 18h, 18i, and unwanted amplitude side lobes 62.

Referring to FIG. 24B, substrate 102 receives incident radiation 16a having plane wavefront 89a through its upper surface 107a. Radiation 16b with wavefront 89b continues through and exits substrate 102 without distortion. Upon exiting substrate 102 at lower surface 107b, radiation component 16c enters cladding 86 and continues in the direction normal to surface 107b. Radiation components 16d,16e, 16f, 16g, 16h, 16i pass into index matching material 160 and subsequently into cladding 86 without distortion of wavefront 89. Index matching material 160 is able to substantially eliminate wavefront distortion.

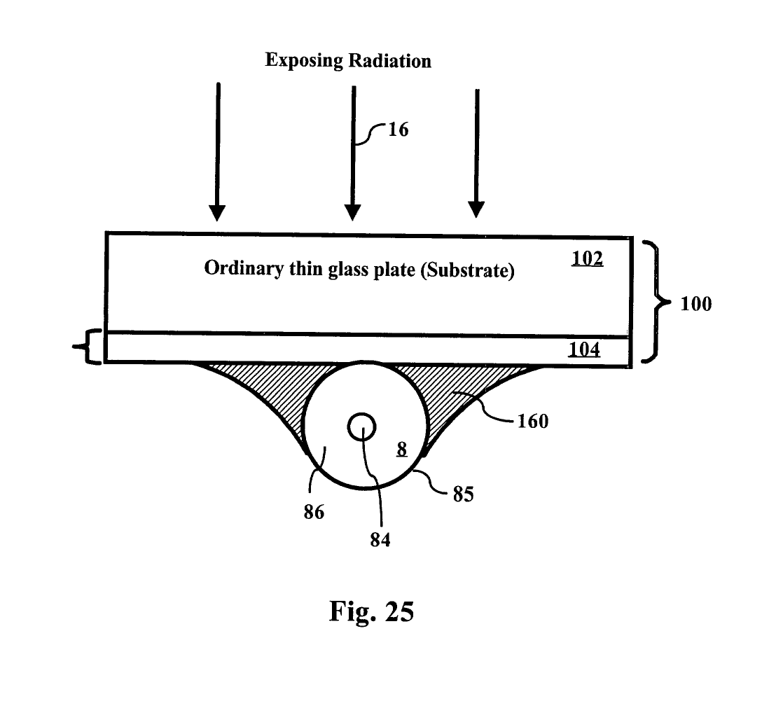

Referring to FIG. 25, index matching material 160 is used with volume hologram phase mask 100, and optical media 8 in accordance with the invention to essentially eliminate wavefront distortion during the actinic exposure process of optical media 8. Optical media 8 may be an optical fiber 82, planar media 8b, media having a non-flat surface, or actinicly susceptible media of other shapes that can benefit by the elimination of wavefront distortion.

If a relief-type phase mask 10 were to be used, index-matching material 160 would fill etched slots 15 of the structure and either totally eliminate or dramatically reduce any useful diffraction, rendering the mask useless for its intended purpose. Wavefront distortion is typically a second-order effect, of lesser consequence than having unwanted diffraction orders. When using a relief-type mask structure 10 it may not provide significant advantage to use index matching material 160 to eliminate wavefront distortion, because the intrinsically obtainable isolation does not warrant the extra effort, and little, if anything, may be gained. Conversely, a volume hologram phase mask 100 in accordance with the invention provides significantly enhanced channel isolation, down to the level of the background noise 68. Use of index matching material 160 in conjunction with volume hologram phase mask 100 provides the most precise results when non-optically flat surfaces are included.

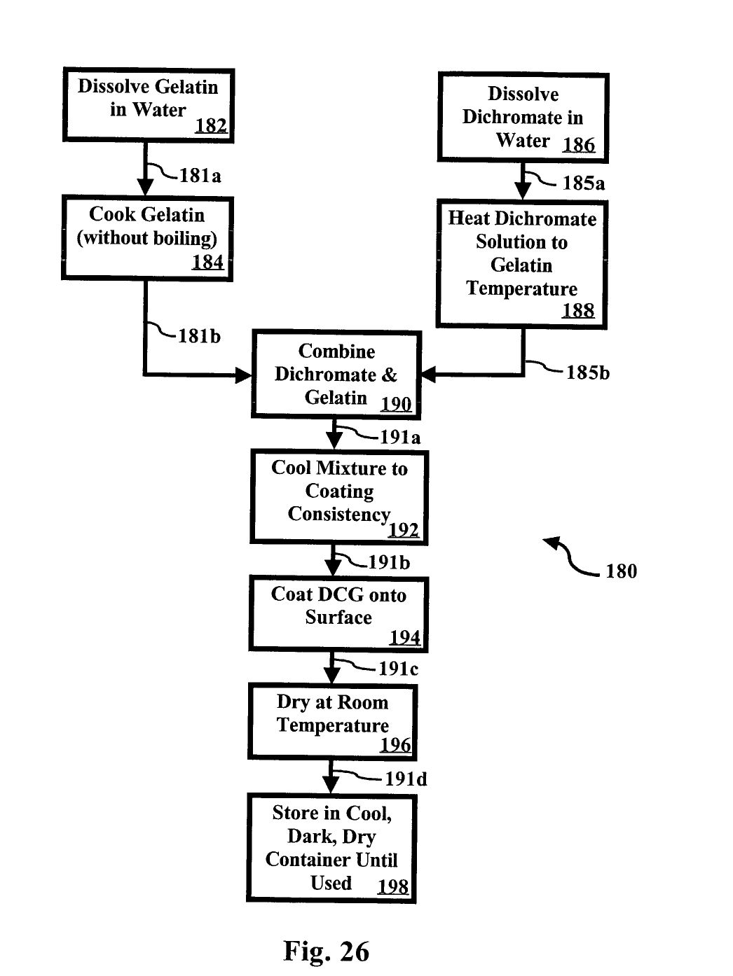

Referring to FIG. 26, preparation of dichromated gelatin (DCG) media is detailed in process 180. The gelatinous fraction of dichromated gelatin is prepared in path 181, while the dichromate portion is prepared along path 185, after which the two parts are combined in step 190 and processed together on path 191. Gelatin is first dissolved in pure water in step 182. De-ionized (DI) water is adequate. The gelatin is then cooked at temperatures between 40 and 70 degrees centigrade in step 184. Dichromate is dissolved in pure (DI) water in step 186, and heated to match the temperature of the cooked gelatin of step 184. The gelatin solution from step 184 and the dichromate solution from step 188 are combined in step 190, after which the mixture is cooled to coating consistency in step 192. The mixture is then coated onto the desired surface in step 194. In one preferred embodiment DCG material is cast in a mold. In a second preferred embodiment the holographic media is applied to the desired surface by spraying. Electrostaticly charged surfaces may be used to alter the spray distribution. In another preferred embodiment, DCG material is spin-coated on a clean surface until the desired thickness is achieved. The surface may be glass, plastic, or any other suitable material. After coating, the DCG material should be dried at room temperature in step 196 and stored in a cool, dark, dry environment until used, as shown in step 198. All surfaces used with the prepared DCG material should be clean, free of moisture, impervious to moisture, and chemically non-reactive. Storage life for unused, unexposed DCG plates, is about one month, when properly stored. Repeatability may be an important issue, if manufacturing process steps are not performed using the same procedure each time. Prepared thin optical plates containing standardized DCG material may be purchased commercially. If commercial plates are used, one must

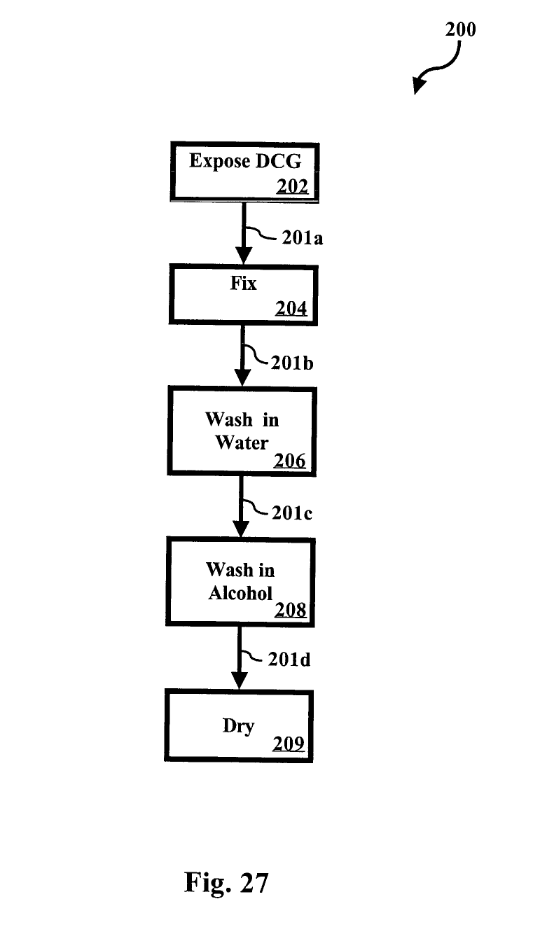

Referring to FIG. 27, development process 200 is outlined for DCG along path 201. The DCG plate is exposed in step 202, Chemically fixed using a commercial fixing agent in step 204, washed successively in pure water and alcohol in steps 206 and 208, respectively, and then dried. The finished hologram should be kept dry, sealed, or otherwise protected from moisture in order to preserve its integrity.

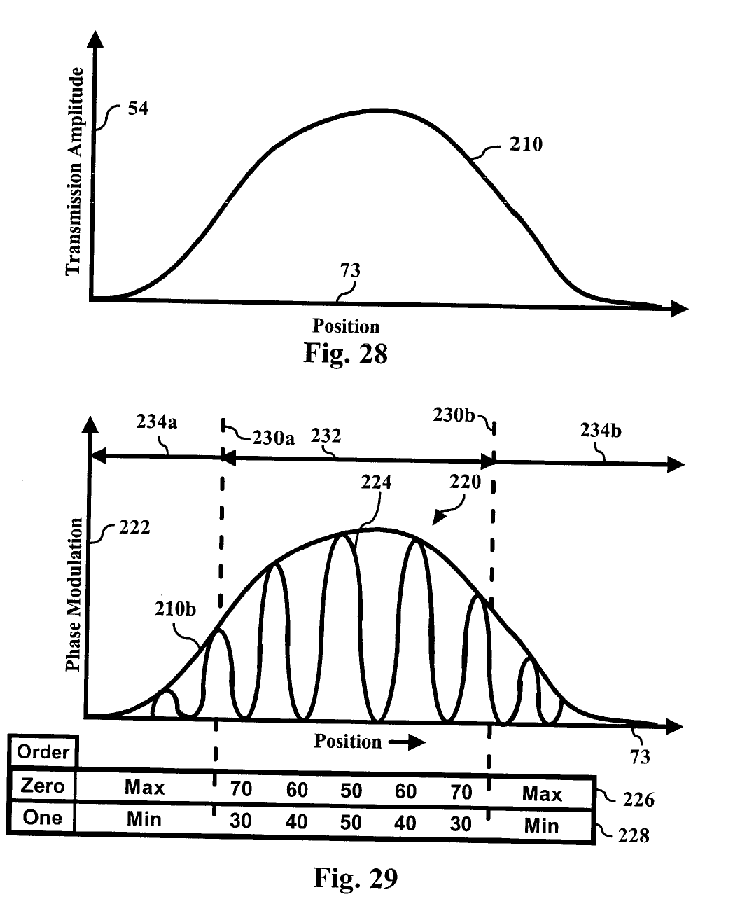

Referring to FIG. 28, amplitude profile 210 of an amplitude transmission mask is a function of position 73 and transmission amplitude 54. Preferred embodiments of profile 210 may be gaussian, quasi-gaussian, linear, or variations thereof. Amplitude masks may be fabricated by several methods. Common photographic silver-halide chemistry is adequate for developing such masks. A number of other methods for varying the transmissivity amplitude across the mask are possible including using variable metallization thickness, variable slit widths, varying scan rates, variable radiation intensity, and combinations of the above.

Referring to FIG. 29 specifically, while referring generally to FIGS. 28 and 29, phase profile 220 of an apodized phase mask in accordance with the invention is a function of position 73 and phase modulation 222. The resultant apodized phase grating profile 224 is composed of a phase grating portion (224) encompassed within the envelope of amplitude profile 210b. The method of superposing the two profiles is accomplished by using the transmission amplitude mask 210 to change the magnitude of diffraction components “zero” 226 and “one” 228 as a function of position along the waveguide fiber 73 during the grating recording process. The amplitude mask profile is used to induce a change in diffraction efficiency in the original phase mask to apodize it as it is recorded. As the relative amplitudes of the two interferometrically interacting diffraction orders change, so does the diffraction efficiency. When magnitudes of the two diffraction orders are large and comparable in magnitude, as in region 232, maximum diffraction efficiency is obtained. Region 232 is the high diffraction efficiency region. Regions 234a and 234b are low diffraction efficiency regions. When the two diffraction orders 226, 228 are unequal, as in regions 234a and 234b, reduced diffraction efficiency results. Changes in diffraction efficiency made in accordance with the invention do not reduce the total radiation exposure level passing through the apodized volume hologram phase mask. Maintaining an essentially constant radiation flux passing through the phase mask while concomitantly incorporating apodization makes “multi-step” processing unnecessary. The result is an apodized phase mask capable of producing the desired apodized structure such as shown in grating profile 76d in a single exposure process step. Practice of the invention makes it possible to efficiently produce high quality gratings and other devices in optical fiber, planar geometries, and the like, that are apodized, short, efficient, free from unwanted side-lobe remnants, and free of unwanted reflections.

A phase mask prepared according to the invention incorporates apodization information intrinsically therein due to the variation of the diffraction efficiency along the length of the mask while still maintaining constant the total energy transmitted at each position on the mask. A phase mask created according to the invention incorporates apodization information without the reduction in amplitude produced by standard “amplitude” masks. The ratio of the diffraction orders coming out of a mask designed according to the invention changes by design, thus changing the visibility of the interference pattern. A phase mask designed according to the invention can then be used to fabricate apodized gratings and other diffraction structures using essentially all of the techniques known in the art involving phase masks. Such techniques include but are not limited to: static exposure of optical media through the mask, scanning the actinic radiation from the source over the optical media, relative motion between the mask, actinic source, and actinicly susceptible media, focusing using lenses, and combinations of the same.

From the above discussion, it will be appreciated that the present invention provides high quality low cost phase masks using volume holograms. Unapodized and apodized volume hologram phase masks using planar and other geometries are according to the invention.

The present invention may be embodied in other specific forms without departing from its structures, methods, or other essential characteristics as broadly described herein and claimed hereinafter. The described embodiments are to be considered in all respects only as illustrative, and not restrictive. The scope of the invention is, therefore, indicated by the appended claims, rather than by the foregoing description. All changes which come within the meaning and range of equivalency of the claims are to be embraced within their scope.

What is claimed and desired to be secured by United States Letters Patent is:

1. A phase mask comprising:
a substantially planar support medium;
a volume hologram with apodization incorporated intrinsically therein contained
within said substantially planar support medium.

2. The phase mask of claim 1, wherein said apodization is inseparable from said volume hologram.

3. The phase mask of claim 1, further comprising a grating region, wherein said apodization maintains a constant average refractive index throughout said grating region.

4. The phase mask of claim 1, further comprising a grating region, wherein said apodization maintains an average transmittance throughout said grating region.
